(19) United States
(12) Patent Application Publication
(10) Pub. No.: US 2026/0279479 A1
(43) Pub. Date: Sep. 17, 2026

(54) METHOD AND ARCHITECTURE FOR EFFICIENT DELAY DECODER TEST OF MEMORIES

(71) Applicant: STMicroelectronics International N.V., Geneva (CH)

(72) Inventors: Rupesh SINGH, Ghaziabad (IN); Ankur BAL, Greater Noida (IN); Archit GUPTA, Faridabad (IN)

(73) Assignee: STMicroelectronics International N.V., Geneva (CH)

(21) Appl. No.: 19/344,016

(22) Filed: Sep. 29, 2025

Related U.S. Application Data
(60) Provisional application No. 63/705,385, filed on Oct. 9, 2024.

(51) Int. Cl. G11C 29/18; G11C 29/12

(52) U.S. Cl. CPC G11C 29/18; G11C 29/1201; G11C 29/12015; G11C 2029/1802

(57) ABSTRACT

An integrated circuit includes a test circuit that tests an address decoder of a memory array in an effective and efficient manner. Each memory cell of the memory array includes an address having n bits. The test circuit performs a built-in self-test (BIST) that provides a sequence of addresses to the address decoder that covers all possible transitions of the address bits in rounds of three cycles.

### BACKGROUND

### Technical Field

This present disclosure is related to computer memory, and more particularly, to signal timing of memories.

### Description of the Related Art

Integrated circuits typically include memory circuits. In some cases, it is beneficial to perform tests of the memory circuits prior to operation of the memory circuits. Such tests utilize both time and resources. In the cases of large memory arrays, such tests can utilize particularly large amounts of time and resources.

All of the subject matter discussed in the Background section is not necessarily prior art and should not be assumed to be prior art merely as a result of its discussion in the Background section. Along these lines, any recognition of problems in the prior art discussed in the Background section or associated with such subject matter should not be treated as prior art unless expressly stated to be prior art. Instead, the discussion of any subject matter in the Background section should be treated as part of the inventor's approach to the particular problem, which, in and of itself, may also be inventive.

### BRIEF SUMMARY

Embodiments of the present disclosure provide test circuit and corresponding method that tests an address decoder of a memory array in an effective and efficient manner. Each memory cell of the memory array includes an address having n bits. The test circuit performs a built-in self-test (BIST) that provides a sequence of addresses to the address decoder that covers all possible transitions of the address bits.

In one embodiment, the test circuit provides addresses in rounds of 3 addresses. In a first round, a first address is provided, a second address is provided by inverting the first address, and the third address is provided by inverting the second address. At the beginning of the next round (and all subsequent rounds), the final address of the previous round is incremented or decremented to provide the first address of that round. The second and third addresses of the round are then generated by performing two inversion operations as described in relation to the first round. This continues until all address transitions have been provided.

In one embodiment, a method includes providing, in each of a plurality of rounds of a memory test process, a plurality of address values from an output terminal of a multiplexer of a test circuit to an input terminal of an address register of the test circuit. The method includes selecting, in each round, a first input terminal of the multiplexer in a first clock cycle of the round, selecting, in each round, a second input terminal of the multiplexer in a second clock cycle of the round subsequent to the first clock cycle, and selecting, in each round, the second input terminal of the multiplexer in a third clock cycle of the round subsequent to the second clock cycle.

In one embodiment, a method includes coupling, on a first clock cycle of a round of a memory test process, an output terminal of a bit adjuster to an input terminal of an address register and coupling, on a second clock cycle of the round subsequent to the first clock cycle, an output terminal of an inverter to the input terminal of the address register. The method includes coupling, on a third clock cycle of the round subsequent to the second clock cycle, the output terminal of the inverter, wherein an output terminal of the address register is coupled to an input terminal of the inverter and to an input terminal of the bit adjuster.

In one embodiment, an integrated circuit includes a memory circuit including an address decoder and a plurality of memory cells and a test circuit configured to output a sequence of address values to the address decoder in a memory test process. The test circuit includes an address register having an output terminal coupled to an input terminal of the address decoder and a multiplexer having an output terminal coupled to an input terminal of the address register, a first input terminal, a second input terminal, and a selection control input terminal. The test circuit includes a selection control circuit having an output terminal coupled to the selection control input terminal of the multiplexer and configured to provide, during the test process, a plurality of rounds of selection control values to the selection control input terminal of the multiplexer. In each round the selection control value selects the first input terminal of the multiplexer on a first clock cycle and selects the second input terminal of the multiplexer on consecutive second and third clock cycles of the round subsequent to the first clock cycle.

In one embodiment, an integrated circuit includes a memory circuit and a test circuit coupled to the memory circuit. The test circuit includes a multiplexer having a selection control input terminal and a selection control circuit. The selection control circuit includes a first logic gate having a first input terminal, a second input terminal, and an output terminal coupled to the selection control input terminal of the multiplexer. The selection control circuit includes a first flip-flop including a data output terminal coupled to the first input terminal of the first logic gate. The selection control circuit includes a second flip-flop including a data output terminal coupled to the second input terminal of the first logic gate and a data input terminal coupled to the data output terminal of the first flip-flop.

### BRIEF DESCRIPTION OF THE SEVERAL VIEWS OF THE DRAWINGS

FIG. 1A is a block diagram of an integrated circuit including a memory array and a memory test circuit having a multiplexer, in accordance with one embodiment.

FIG. 1B illustrates which input terminal of the multiplexer of the test circuit of FIG. 1A is selected in each cycle of each of a plurality of rounds of an ad recessing process, in accordance with one embodiment.

FIG. 2A is a schematic diagram of an integrated circuit including a memory array and the memory test circuit, in accordance with one embodiment.

FIG. 2B illustrates a sequence of addresses provided from the test circuit to an address decoder of the memory array of FIG. 2A during a test process, in accordance with one embodiment.

FIG. 3A is a schematic diagram of an integrated circuit including a memory array and the memory test circuit, in accordance with one embodiment.

FIG. 3B illustrates a sequence of addresses provided from the test circuit to an address decoder of the memory array of FIG. 3A during a test process, in accordance with one embodiment.

FIG. 4 is a flow diagram of a method for performing a test of an address decoder of a memory array, in accordance with one embodiment.

FIG. 5 is a flow diagram of a method for performing a test of an address decoder of a memory array, in accordance with one embodiment.

### DETAILED DESCRIPTION

In the ensuing description, various specific details are illustrated aimed at enabling an in-depth understanding of the embodiments. The embodiments may be provided without one or more of the specific details, or with other methods, components, materials, etc. In other cases, known structures, materials, or operations are not shown or described in detail so that various aspects of the embodiments will not be obscured.

Reference to “an embodiment” or “one embodiment” in the framework of this description is meant to indicate that a particular configuration, structure, or characteristic described in relation to the embodiment is comprised in at least one embodiment. Hence, phrases such as “in an embodiment”, “in one embodiment”, or the like that may be present in various points of this description do not necessarily refer to one and the same embodiment. Moreover, particular conformations, structures, or characteristics may be combined in any adequate way in one or more embodiments.

In the following description, certain specific details are set forth in order to provide a thorough understanding of various disclosed embodiments. However, one skilled in the relevant art will recognize that embodiments may be practiced without one or more of these specific details, or with other methods, components, materials, etc.

Unless the context requires otherwise, throughout the specification and claims which follow, the word “comprise” and variations thereof, such as, “comprises” and “comprising” are to be construed in an open, inclusive sense, that is as “including, but not limited to.” Further, the terms “first,” “second,” and similar indicators of sequence are to be construed as interchangeable unless the context clearly dictates otherwise.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its broadest sense, that is as meaning “and/or” unless the content clearly dictates otherwise.

As used herein, “source/drain terminal” can refer to a source terminal of a transistor or a drain terminal of a transistor.

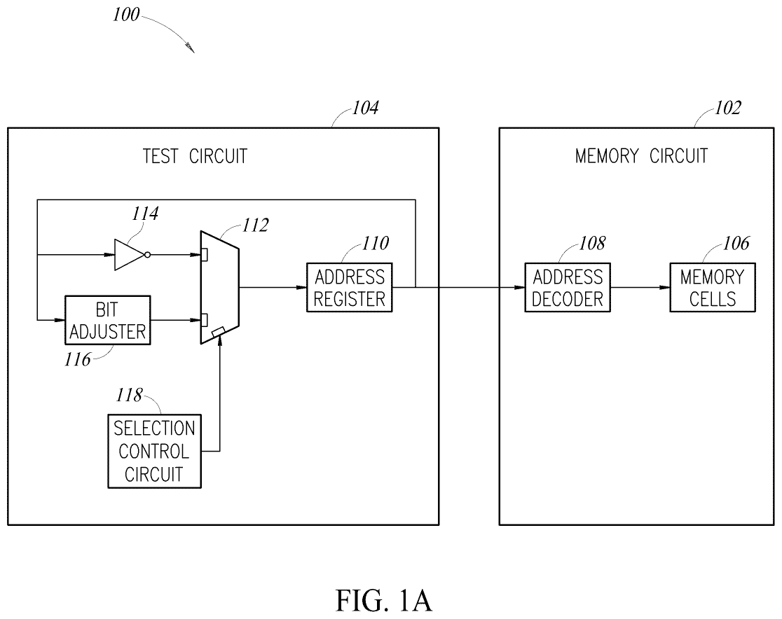

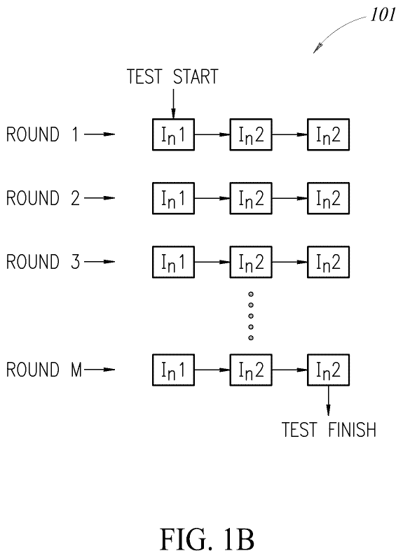

FIG. 1A is a block diagram of an integrated circuit 100, in accordance with one embodiment. The integrated circuit 100 includes a memory circuit 102 and a test circuit 104. As will be set forth in more detail below, the test circuit performs an address test of the memory circuit 102 in an effective and efficient manner.

In one embodiment, the integrated circuit 100 is a system on chip (SoC), though other types of integrated circuits can be utilized without departing from the scope of the present disclosure. In one embodiment, the integrated circuit 100 is installed in a device a smart phone, smartwatch, a tablet, a laptop computer, a vehicle, a medical device, an industrial device, or other types of devices or machines.

In one embodiment, the memory circuit 102 includes a plurality of memory cells 106. The plurality of memory cells 106 can correspond to an array of memory cells. In one embodiment, the memory cells are read-only memory cells. In one embodiment, the memory cells are random access memory cells. The memory cells can include static random-access memory cells, dynamic random-access memory cells, electrically erasable or programmable read-only memory cells, or other types of memory cells.

Each memory cell 106 has an address. The address has n bits. The value of n is based on the number of memory cells 106 of the memory array. The larger the number of memory cells 106, the larger the number of bits in the address of each memory cell 106. When data is to be read from a particular memory cell 106 or when data is to be written to a particular memory cell 106, the memory circuit 102 receives the address of the memory cell (or cells) 106 that performs the operation of the corresponding memory cell 106.

In one embodiment, the memory circuit 102 includes an address decoder 108. The address decoder 108 is utilized to decode addresses for the read operations and write operations of the memory cells 106. In particular, during operation of the memory circuit 102, the address decoder 108 receives one or more addresses of memory cells 106 for which a read or write operation is to be performed. The address decoder 108 decodes the addresses and the read or write operation is then performed on the memory cells 106 of the corresponding addresses.

It is beneficial to test various aspects of the memory circuit 102 prior to using the memory circuit 102 in order to ensure that the memory circuit 102 is functioning properly. One aspect of the memory circuit 102 that can be tested is the address decoder 108. In particular, it is beneficial to ensure that the address decoder 108 can accurately decode addresses received in any sequence. For example, it is beneficial to test that the address decoder 108 can decode addresses for all possible transitions of the address bits.

The integrated circuit 100 utilizes the test circuit 104 to perform a BIST for the address decoder 108 of the memory circuit 102. In particular, during the BIST the test circuit 104 provides a sequence addresses to the memory circuit 102. The test circuit 104 generates the sequence of addresses in a manner that is efficient in terms of time and processing resources, as well as in a manner that is effective to fully test the address decoder 108.

In one embodiment, the BIST is performed as a wafer level test of the memory circuit 102. For example, the integrated circuit 100 is initially process as part of a wafer that includes a large number of identical integrated circuits. Each integrated circuit 100 in the wafer includes a memory circuit 102. After processing of the wafer is substantially complete, an external testing device is coupled to test pads of each integrated circuit to cause the test circuit 104 to perform the BIST of the address decoder 108. In this way, the memory circuit 102 of each integrated circuit of a wafer is tested prior to dicing the wafer.

In one embodiment, the BIST is performed after the integrated circuit 100 has been installed in a device. For example, the test circuit 104 may be configured to perform the BIST each time the integrated circuit 100 is powered on. In one embodiment, the test circuit 104 performs the BIST at selected intervals. A control circuit of the integrated circuit 100 can control the test circuit 104 to perform the BIST in accordance with a particular schedule, a particular pattern, or in response to selected conditions of the integrated circuit 100.

As described previously, the address decoder is one of the main components of memory systems. The delay decoder algorithm is employed to test the decoder logic. An address sequence is generated to cover all possible transitions of the address bits. It is beneficial to cover all the transitions with a small number of address patterns in order to reduce the BIST runtime. Reducing the test time directly impact the cost.

In one possible solution, and algorithm is implemented that includes multiple combinations of read and write operations with a predefined address sequence then utilized to cover testing of the decoder logic of the address decoder 108. The address pattern sequence covers all possible transitions of address bits during the read operation. In the example of a 3-bit address, the following sequence of addresses can be used as a first half of the BIST:

$$000 -> 111 -> 001 -> 110 -> 010 -> 101 -> 011 -> 100.$$

This first half of the BIST corresponds to an increment mode. In particular, an address initial address (e.g., 000) is provided, a second address (111) is generated by inverting the first address. A third address (001) is generated by inverting the second address and then incrementing by 1. This continues until the value 100 is provided.

After performing the first half of the BIST, the second half of the BIST is performed including the following sequence:

$$111 -> 000 -> 110 -> 001 -> 101 -> 010 -> 100 -> 11.$$

This second half of the BIST corresponds to a decrement mode. In the decrement mode, an address initial address (e.g., 111) is provided, a second address (000) is generated by inverting the first address. A third address (110) is generated by inverting the second address and then decrementing by 1. This continues until 011 is provided. The combination of the increment mode and the decrement mode covers all possible transitions of the address bits.

The possible solution described above utilizes 2*2\hat{ }n clock cycles. In other words, the possible solution described above provides 2*2\hat{ }n addresses to the address decoder. Assuming the addresses are provided in consecutive clock cycles, this results in at least 2*2\hat{ }n clock cycles for providing the addresses.

In one embodiment, the test circuit 104 provides the addresses in a sequence that utilizes fewer addresses than the possible solution described above. In particular, the test circuit 104 provides the addresses in the single sequence that corresponds to a combination of both incrementing and decrementing, as will be described in more detail below.

In one embodiment, the test circuit 104 includes an address register 110 and the multiplexer 112. Though not shown in FIG. 1A, the integrated circuit 100 includes a clock generator that generates the clock signal. The clock signal is provided to the test circuit 104 and the memory circuit 102. During the BIST, the multiplexer 112 provides an address to the address register 110 on each clock cycle. On each clock cycle, the address register 110 outputs the previously stored address to the address decoder 108 and replaces the previously stored address with the new address received from the multiplexer 112. This continues until the complete sequence of addresses has been provided to the address decoder 108.

In one embodiment, the test circuit includes a bit adjuster 116, and a selection control circuit 118. The bit adjuster 116 has an input terminal coupled to the output terminal of the address register 110 and an output terminal coupled to a first input terminal of the multiplexer 112. The inverter 114 has an input terminal coupled to the output terminal of the address register 110. The inverter 114 has an output terminal coupled to a second input terminal of the multiplexer 112. The selection control circuit 118 is coupled to a selection control input terminal of the multiplexer 112.

On each clock cycle, the multiplexer 112 outputs the value provided to the first or to the second input, based on the value of a selection control signal received at the selection control input. In one example, when the value of the selection control signal is 0, the second input (output terminal of the inverter 114) is selected. When the value of the selection control signal is 1, the first input terminal (output terminal of the bit adjuster 116) is selected.

On each clock cycle, the inverter 114 receives the address most recently output by the address register 110 and inverts this value. The bit adjuster 116 receives the address most recently output by the address register 110 and adjusts this value. In one embodiment, the bit adjuster increments the value received from the address register 110. In one embodiment, the bit adjuster increments the value received from the address register 110.

In one embodiment, the selection control circuit 118 generates the selection control signal so that the first input terminal of the multiplexer 112 is selected on a first clock cycle of a group of three clock cycles. The selection control circuit 118 generates the selection control signal so that the second input terminal of the multiplexer 112 is selected for the second and third clock cycles of the round. After the 2 consecutive clock cycles for which the second input is selected, the selection control circuit 118 generates the selection control signal so that the first output terminal of the multiplexer 112 is selected on the first cycle of the next round. After selecting the first input for the single clock cycle, the selection control circuit 118 again selects the second input for the remaining two consecutive clock cycles of the round. This pattern repeats until the entire sequence of addresses has been generated.

In one embodiment, it can be considered that the test circuit 104 generates addresses in rounds of 3. In other words, in each round, three addresses are provided to the address register 110, and from the address register 110 to the address decoder 108. In each round, the first input terminal of the multiplexer 112 is twice and the second input terminal of the multiplexer 112 is selected twice consecutively. In other words, in each round, the output terminal of the bit adjuster 116 is selected once, while the output terminal of the inverter 114 is selected twice consecutively.

FIG. 1B includes an illustration 101 indicating which input terminal of the multiplexer 112 is selected for each cycle of a BIST, in accordance with one embodiment. The sequence of addresses for the BIST is generated in M rounds. Each round includes 3 clock cycles. In the first cycle of each round, the first input is selected. In the second and third clock cycles of each round, the second input is selected. In other words, the output terminal of the bit adjuster 116 is selected once and the output terminal of the inverter 114 is selected in the second and third clock cycles of each round. The result is that all possible that transitions are tested in (3/2)*2\hat{ }n cycles, where n is the number of bits in each address. Stated otherwise, the sequence of addresses includes (3/2)*2\hat{ }n addresses. This is significantly smaller number of addresses than the number of addresses (2*2\hat{ }n) utilized in the other possible solution described above. The number of cycles saved with the test circuit 104 of FIG. 1A increases for larger addresses. Accordingly, the test circuit 104 of FIG. 1A effectively and efficiently generate a sequence of addresses for a BIST that covers all possible that value transitions.

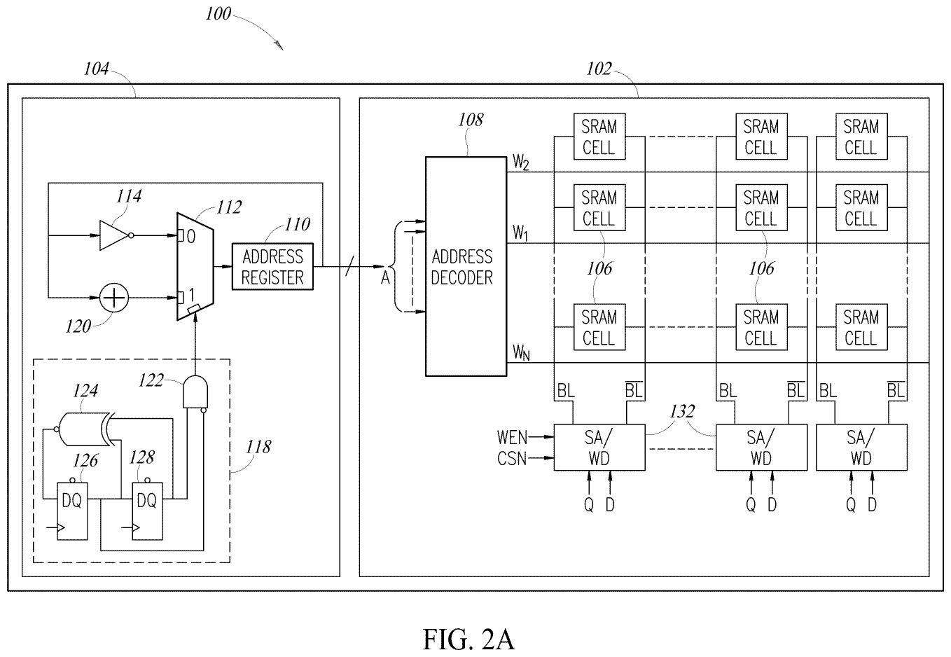

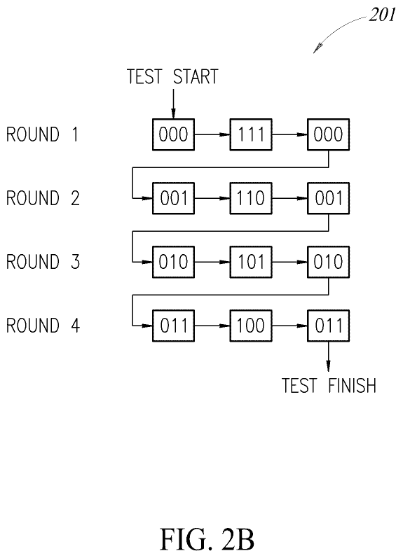

FIG. 2A is a schematic diagram of an integrated circuit 100, in accordance with one embodiment. The integrated circuit 100 of FIG. 2A is one example of the integrated circuit 100 of FIG. 1A.

The integrated circuit 100 includes a memory circuit 102. The memory circuit 102 includes an array of memory cells 106. Each memory cell 106 is an SRAM memory cell. However, other types of memory cells can be utilized without departing from the scope of the present disclosure. The memory cells 106 are arranged in rows and columns. Each row is coupled to a word line WL. Each column of memory cells is coupled to a pair of bitlines BL and B̅L̅. BL is the true bitline and B̅L̅ is the false bitline. Each pair bitlines is coupled to a sense amplifier 132 (SA/WD). Each sense amplifier receives the control signals WEN and CSN.

The memory circuit 102 includes an address decoder 108. The address decoder 108 is coupled to the word lines and the sense amplifiers. The address decoder 108 receives an address of a memory cell for a read operation or a write operation and selects/enables the corresponding word line and sense amplifier 132.

The integrated circuit 100 includes a test circuit 104. The test circuit 104 includes an address register 110, a multiplexer 112, and inverter 114, and an the incremental 120 is one example of the bit adjuster 116 of Figure one a. The test circuit 104 includes a selection control circuit 118. The selection control circuit 118 of FIG. 2A is one example of the selection control circuit 118 of FIG. 1A.

The test circuit 104 performs a BIST on the address decoder 108. The BIST includes outputting a sequence of addresses to the address decoder 108. The sequence of addresses a selected to ensure that all possible bit transitions are tested for the address decoder 108.

The test circuit 104 operates in a manner substantially similar to that described in relation to FIG. 1A. In particular, the selection control circuit 118 selects the first input (1) of the multiplexer 112 in the first cycle of each round. The selection control circuit 118 selects the second input (0) of the multiplexer 112 on the second and third cycle of each round.

The selection control circuit 118 includes an AND gate having an output terminal coupled to the selection control input terminal of the multiplexer 112. Accordingly, the output terminal of the AND gate corresponds to the output terminal of the selection control circuit 118. The selection control circuit 118 includes an XNOR gate 124, a first flip-flop 126, and a second flip-flop 128.

The data output terminal Q is coupled to the data input terminal D of the flip-flop 128, to an inverting input terminal of the AND gate 122 a first input terminal of the XNOR gate 124. The data output terminal Q of the second flip-flop 128 is coupled to a second input terminal of the AND gate 122 and to a second input terminal of the XNOR gate 124. The output terminal of the XNOR gate 124 is coupled to the data input terminal D of the flip-flop 126. The flip-flops 126 and 128 each receive the clock signal on the clock input terminals.

The selection control circuit 118 corresponds to a type of three stage counter, in one embodiment. On the first stage, the output terminal of the AND gate is high (1), and the corresponding input terminal of the multiplexer 112 is selected. On the second stage and the third stage, the output terminal of the AND gate is low (0) and the corresponding input terminal of the multiplexer 112 is selected. After the third stage, the input terminal of the AND gate is 10, which is converted to 11 because the inverted input. This causes the output terminal of the AND gate 122 to return to the high value for the beginning of the next round.

FIG. 2B is illustrates a sequence of addresses generated for a BIST by the test circuit 104 of FIG. 2A, in an example in which the addresses are 3-bit addresses (n=3). In the first cycle of the first round, the incrementor 120 outputs an initial value of 000 as input 1 of the multiplexer is selected. In the second cycle of the first round, the inverter 114 outputs the value 111 by inverting the value 000 outputting the first cycle, as the output 0 of the multiplexer 112 is selected. In the third cycle of the first round, the inverter 114 outputs the value 000 by inverting the value 111 output in the second cycle, as the output 0 of the multiplexer 112 is selected. In the first cycle of the second round, the input 1 is again selected and the incrementor 120 provides the value 001 by incrementing the value 000 output in the third cycle of the first round. This value is then inverted twice in the second and third cycles of the second round to provide the values 110 and 001. In the first cycle of the third round, the input 1 is again selected and the incrementor 120 provides the value 010 by incrementing the value 001 output in the third cycle of the second round. This value is then inverted twice in the second and third cycles of the third round to provide the values 101 and 010. In the first cycle of the fourth round, the input 1 is again selected and the incrementor 120 provides the value 011 by incrementing the value 010 output in the third cycle of the third round. This value is then inverted twice in the second and third cycles of the fourth round to provide the values 100 and 011. After the 4th round, the BIST is complete as all possible transitions have been tested in (3/2)*2\hat{ }3=12 clock cycles. This is in contrast to the 16 clock cycles utilized in the other possible solution that includes a first half of incrementing and a second half of decrementing.

Returning to FIG. 2A, those of skill in the art will recognize that other circuit architectures can be utilized for the selection control circuit 118 to generate a 3-round cycle. Also each other circuit architectures fall within the scope of the present disclosure.

In one embodiment, the BIST includes writing known values to each of the memory cells 106. The BIST includes reading the data values from the memory cells in accordance with the sequence of addresses provided to the address decoder 108. If the data read from the memory cells 106 matches the known data than the test circuit 104 determines that the address decoder 108 is functioning properly.

In one embodiment, the BIST includes writing a data value of 1 to each of the memory cells 106 prior to providing the sequence of addresses to the address decoder 108. During the BIST, each time a value is read from the memory cells in accordance with the sequence of addresses, that memory cell is rewritten as 0. If a value of 0 is ever read from of the memory cells during the BIST, then this is an indication that the address decoder has erroneously read twice from a single memory cell. This indicates that the address decoder 108 is not functioning properly. Various other schemes can be utilized to detect malfunction of the address decoder 108 in accordance with a BIST or other type of test without departing from the scope of the present disclosure.

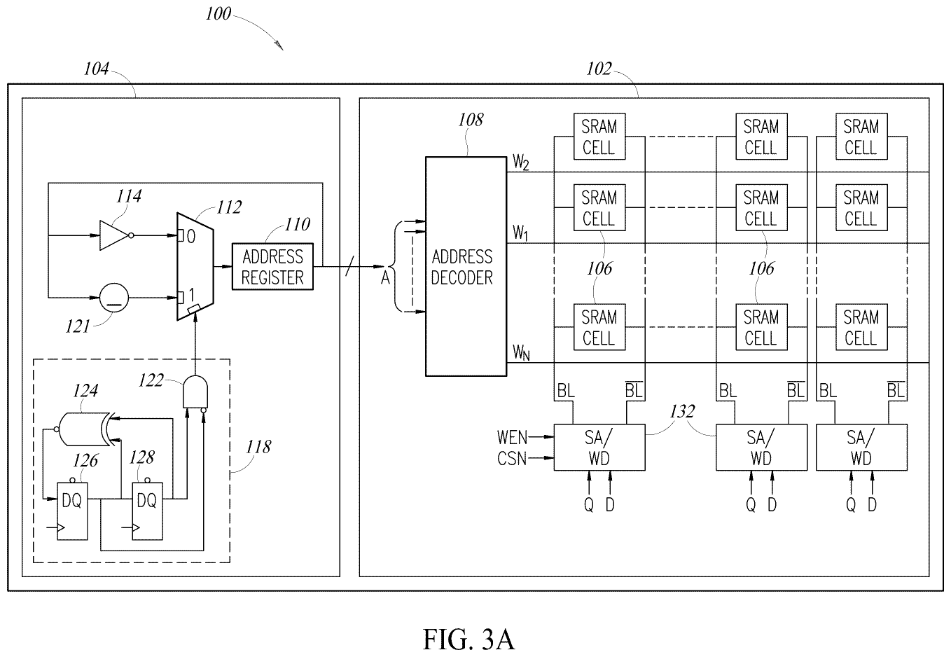

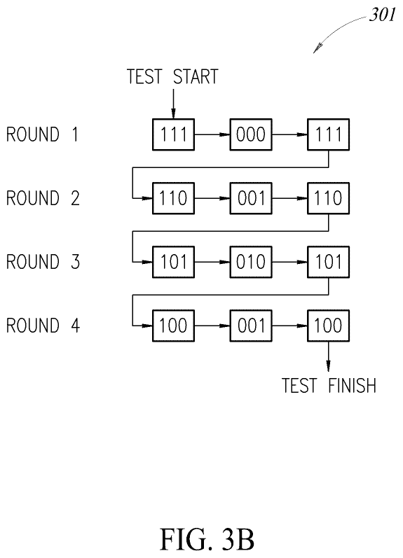

FIG. 3A is a schematic diagram of an integrated circuit 100, in accordance with one embodiment. The integrated circuit 100 of FIG. 3A is one example of the integrated circuit 100 of FIG. 1A. The integrated circuit 100 of FIG. 3A is substantially similar to the integrated circuit 100 of FIG. 2A, except that a decrementor 121 is utilized instead of an increment or 120. In this case, the decrement or 121 outputs an initial value of 111 (in the example of 3-bit address) and then decrements subsequently received values.

FIG. 3B provides an illustration 301 of a BIST sequence generated by the test circuit 104 of FIG. 3A, in accordance with one embodiment. In the first cycle of the first round, the decrementor 121 outputs an initial value of 111 as input 1 of the multiplexer is selected. In the second cycle of the first round, the inverter 114 outputs the value 000 by inverting the value 111 output in the first cycle, as the output 0 of the multiplexer 112 is selected. In the third cycle of the first round, the inverter 114 outputs the value 111 by inverting the value 000 output in the second cycle, as the output 0 of the multiplexer 112 is selected. In the first cycle of the second round, the input 1 is again selected and decrementor 121 provides the value 110 by decrementing the value 111 output in the third cycle of the first round. This value is then inverted twice in the second and third cycles of the second round to provide the values 001 and 110. In the first cycle of the third round, the input 1 is again selected and the decrementor 121 provides the value 101 by decrementing the value 110 output in the third cycle of the second round. This value is then inverted twice in the second and third cycles of the third round to provide the values 010 and 101. In the first cycle of the fourth round, the input 1 is again selected and the decrementor 121 provides the value 100 by decrementing the value 101 output in the third cycle of the third round. This value is then inverted twice in the second and third cycles of the fourth round to provide the values 001 and 100. After the 4th round, the BIST is complete as all possible transitions have been tested.

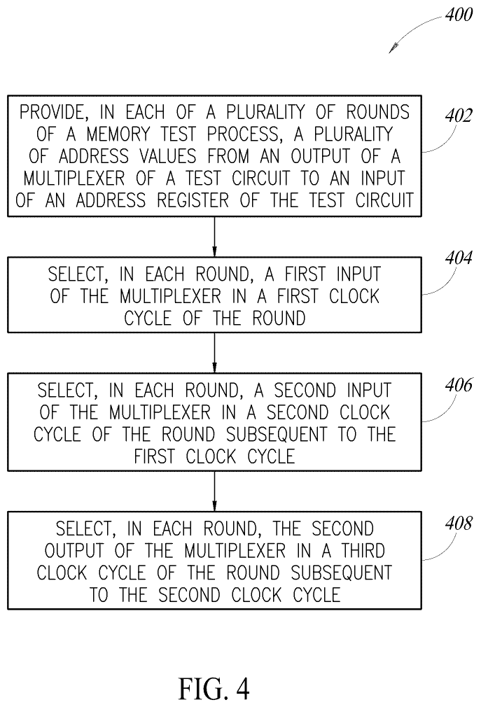

FIG. 4 is a flow diagram of a method 400 for operating a memory circuit, in accordance with one embodiment. The method 400 can utilize components, systems, and processes described in relation to FIGS. 1-3B. At 402, the method 400 includes providing, in each of a plurality of rounds of a memory test process, a plurality of address values from an output terminal of a multiplexer of a test circuit to an input terminal of an address register of the test circuit. At 404, the method 400 includes selecting, in each round, a first input terminal of the multiplexer in a first clock cycle of the round. At 406, the method 400 includes selecting, in each round, a second input terminal of the multiplexer in a second clock cycle of the round subsequent to the first clock cycle. At 408, the method 400 includes selecting, in each round, the second input terminal of the multiplexer in a third clock cycle of the round subsequent to the second clock cycle.

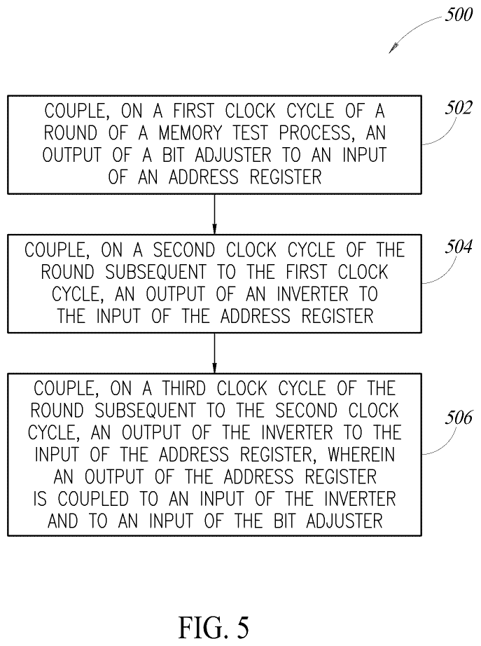

FIG. 5 is a flow diagram of a method 500 for operating a memory circuit, in accordance with one embodiment. The method 500 can utilize components, systems, and processes described in relation to FIGS. 1-3B. At 502, the method 500 coupling, on a first clock cycle of a round of a memory test process, an output terminal of a bit adjuster to an input terminal of an address register. At 504, the method 500 includes coupling, on a second clock cycle of the round subsequent to the first clock cycle, an output terminal of an inverter to the input terminal of the address register. At 506, the method 500 includes coupling, on a third clock cycle of the round subsequent to the second clock cycle, the output terminal of the inverter, wherein an output terminal of the address register is coupled to an input terminal of the inverter and to an input terminal of the bit adjuster.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
providing, in each of a plurality of rounds of a memory test process, a plurality of address values from an output terminal of a multiplexer of a test circuit to an input terminal of an address register of the test circuit;
selecting, in each round, a first input terminal of the multiplexer in a first clock cycle of the round;
selecting, in each round, a second input terminal of the multiplexer in a second clock cycle of the round subsequent to the first clock cycle; and
selecting, in each round, the second input terminal of the multiplexer in a third clock cycle of the round subsequent to the second clock cycle.

2. The method of claim 1, wherein providing the providing the plurality of address values includes:
providing the address values from the output terminal of the multiplexer to an input terminal of an address register; and
providing the address values from an output terminal of the address register to the address decoder.

3. The method of claim 2, wherein an inverter is coupled between an output terminal of the address register and the second input terminal of the multiplexer in a feedback configuration, wherein a bit adjuster is coupled between the output terminal of the address register and the first input terminal of the multiplexer in a feedback configuration.

4. (canceled)

5. The method of claim 3, comprising incrementing, with the bit adjuster the address values output by the address register.

6. The method of claim 3, comprising decrementing, with the bit adjuster the address values output by the address register.

7. The method of claim 1, wherein the memory test process includes a built-in self-test process, wherein each address value has n-bits, where n is an integer, wherein providing the plurality of address values includes providing (3/2)*2\hat{ }n address values.

8. (canceled)

9. The method of claim 1, comprising:
generating, with a selection control circuit, a selection control value; and
providing the selection control value to a selection control input terminal of the multiplexer, wherein:
a data output terminal of a first flip-flop is coupled to a first input terminal of a first logic gate;
a data output terminal of a second flip-flop is coupled to a second input terminal of the first logic gate; and
an output terminal of the first logic gate is coupled to the selection control input terminal of the multiplexer.

10. (canceled)

11. The method of claim 109, wherein:
the data output terminal of the first flip-flop is coupled to a data input terminal of the second flip-flop;
the data output terminal of the first flip-flop is coupled to a first input terminal of a second logic gate;
the data output terminal of the second flip-flop is coupled to a second input terminal of the second logic gate; and
an output terminal of the second logic gate is coupled to a data input terminal of the first flip-flop.

12. (canceled)

13. The method of claim 11, wherein the first logic gate is an AND gate and the second logic gate is an XNOR gate.

14. A method, comprising:
coupling, on a first clock cycle of a round of a memory test process, an output terminal of a bit adjuster to an input terminal of an address register;
coupling, on a second clock cycle of the round subsequent to the first clock cycle, an output terminal of an inverter to the input terminal of the address register; and
coupling, on a third clock cycle of the round subsequent to the second clock cycle, the output terminal of the inverter, wherein an output terminal of the address register is coupled to an input terminal of the inverter and to an input terminal of the bit adjuster.

15. The method of claim 14, wherein the memory test process includes providing a sequence of address values from the address register to an address decoder of a memory circuit.

16. The method of claim 15, wherein the output terminal of the bit adjuster is coupled to a first input terminal of a multiplexer, wherein an output terminal of the multiplexer is coupled to the input terminal of the address register, wherein the output terminal of the inverter is coupled to a second input terminal of the multiplexer.

17. (canceled)

18. The method of claim 16, comprising:
generating, with a selection control circuit, a selection control value; and
providing the selection control value to a selection control input terminal of the multiplexer, wherein:
a data output terminal of a first flip-flop is coupled to a first input terminal of a first logic gate;
a data output terminal of a second flip-flop is coupled to a second input terminal of the first logic gate;
an output terminal of the first logic gate is coupled to the selection control input terminal of the multiplexer; and
the data output terminal of the first flip-flop is coupled to a data input terminal of the second flip-flop.

19. (canceled)

20. The method of claim 18, wherein:
the data output terminal of the first flip-flop is coupled to a first input terminal of a second logic gate;
the data output terminal of the second flip-flop is coupled to a second input terminal of the second logic gate; and
an output terminal of the second logic gate is coupled to a data input terminal of the first flip-flop.

21. An integrated circuit, comprising:
a memory circuit including an address decoder and a plurality of memory cells; and
a test circuit configured to output a sequence of address values to the address decoder in a memory test process, the test circuit including:
an address register having an output terminal coupled to an input terminal of the address decoder;
a multiplexer having an output terminal coupled to an input terminal of the address register, a first input terminal, a second input terminal, and a selection control input terminal; and
a selection control circuit having an output terminal coupled to the selection control input terminal of the multiplexer and configured to provide, during the test process, a plurality of rounds of selection control values to the selection control input terminal of the multiplexer, wherein in each round the selection control value selects the first input terminal of the multiplexer on a first clock cycle and selects the second input terminal of the multiplexer on consecutive second and third clock cycles of the round subsequent to the first clock cycle.

22. The integrated circuit of claim 21, wherein the selection control circuit includes:
a first logic gate having a first input terminal, a second input terminal, and an output terminal coupled to the selection control input terminal of the multiplexer;
a first flip-flop including a data output terminal coupled to the first input terminal of the first logic gate;
a second flip-flop including a data output terminal coupled to the second input terminal of the first logic gate and a data input terminal coupled to the data output terminal of the first flip-flop; and
a second logic gate having a first input terminal coupled to a data output terminal of the first flip-flop, a second input terminal coupled to data output terminal of the second flip-flop, and an output terminal coupled to a data input terminal of the first flip-flop.

23. The integrated circuit of claim 22, wherein the first logic gate is an AND gate and the second logic gate is an XNOR gate.

24. The integrated circuit of claim 21, wherein the test circuit includes:
a bit adjuster coupled between the output terminal of the address register and the first input terminal of the multiplexer; and
an inverter coupled between the output terminal of the address register and the second input terminal of the multiplexer.

25. The integrated circuit of claim 24, wherein the bit adjuster is an incrementor.

26. The integrated circuit of claim 24, wherein the bit adjuster is a decrementor.

27-29. (canceled)
